(19) United States
(12) Patent Application Publication
(10) Pub. No.: US 2012/0068270 A1
(43) Pub. Date: Mar. 22, 2012

(54) SEMICONDUCTOR DEVICE AND MANUFACTURING METHOD OF THE DEVICE

(75) Inventor: Satoru GOTOU, Toyama (JP)

(73) Assignee: PANASONIC CORPORATION, Osaka (JP)

(21) Appl. No.: 13/308,179

(22) Filed: Nov. 30, 2011

Related U.S. Application Data
(63) Continuation of application No. PCT/JP2010/001098, filed on Feb. 19, 2010.

(30) Foreign Application Priority Data
Jul. 15, 2009 (JP) 2009-166528

(51) Int. Cl. H01L 27/088; H01L 21/336

(52) U.S. Cl. 257/368; 438/299; 257/E21.409; 257/E27.06

(57) ABSTRACT

A semiconductor device includes a first transistor including a gate electrode formed on semiconductor substrate with a gate insulating film interposed therebetween, a first sidewall formed on each side surface of the first gate electrode, and a source/drain diffusion layer; and a second transistor including a gate electrode formed on the semiconductor substrate with the gate insulating film interposed therebetween, a first sidewall formed on each side surface of the second gate electrode, a second sidewall formed outside the first sidewall. A nickel silicide layer is formed in each of upper portions of the gate electrode and the source/drain regions in a silicide formation region. The first sidewall is resistant an etching material used for etching the second sidewall.

### CROSS-REFERENCE TO RELATED APPLICATION

This is a continuation of PCT International Application PCT/JP2010/001098 filed on Feb. 19, 2010, which claims priority to Japanese Patent Application No. 2009-166528 filed on Jul. 15, 2009. The disclosures of these applications including the specifications, the drawings, and the claims are hereby incorporated by reference in their entirety.

### BACKGROUND

The present disclosure relates to semiconductor devices and manufacturing methods of the devices, and more particularly to semiconductor devices including silicide layers in source/drain regions of transistors, and manufacturing methods of the devices.

In recent years, in order to meet the demand for higher performance of semiconductor devices, miniaturization has developed to increase the density of transistors per chip. At present, highly miniaturized transistors with nodes of 45 nm are mass-produced. With reduction in sizes according to the scaling predicted by conventional Moore's Law, miniaturization of contacts between gate electrodes and source/drain regions particularly progresses. Since contact resistance of contacts increases with reduction in areas of the contacts, salicidation, i.e., self-aligned silicidation, of upper portions of source/drain regions and gate electrodes is often employed as a means for reducing contact resistance.

On the other hand, transistors for analog applications are also formed on a semiconductor substrate. Silicide layers are not formed in the transistors for the analog applications to provide higher resistance of gate insulating films and effective ESD protection. As such, a silicide formation region, in which a silicide is formed, and a non-silicide-formation region, in which no silicide is formed, need to be separately provided in a single semiconductor substrate.

In salicidation for forming a silicide, the following removal of an insulating film is employed to separately provide a silicide formation region and a non-silicide-formation region. Specifically, the insulating film is deposited on the entire surface of a transistor, the insulating film in the silicide formation region is selectively removed to retain the insulating film in the non-silicide-formation region.

An increasingly prevalent problem is that transistors cannot sufficiently provide high performance simply by reducing the scale according to the conventional Moore's Law, and thus cannot provide desired operating characteristics due to reduction in carrier mobility and drivability.

Various techniques of applying stress to a channel are reported as a means for providing sufficiently high drivability of a transistor.

For example, as a method of applying stress to a channel region, there is a technique of removing a sidewall of a transistor and depositing a stress liner film to cover a gate electrode. This is generally called a “disposable side wall (DSW)” technique. A silicon nitride film, which is formed by plasma chemical vapor deposition (plasma CVD) or low pressure chemical vapor deposition (LP-CVD) and causes predetermined stress, is deposited as a stress liner film used for the DSW technique.

An example manufacturing process of a semiconductor using a conventional salicidation and the DSW technique shown in Japanese Patent Publication No. 2007-208166 and Japanese Patent Publication No. 2009-026795 will be described with reference to FIGS. 13A-13C and 14A-14C. While in these figures, only n-type metal insulator semiconductor field effect transistors (nMISFETs) are shown as transistors formed in a silicide formation region A and a non-silicide-formation region B, pMISFETs are also formed on a substrate.

First, as shown in FIG. 13A, a shallow trench isolation (STI) region 12 having a thickness of 300 nm and made of silicon dioxide is selectively formed in an upper portion of a semiconductor substrate 11 made of silicon. Then, a gate insulating film 13 with a thickness of 2 nm and a polysilicon film with a thickness of 100 nm are sequentially formed on the semiconductor substrate 11. After that, a resist mask is patterned by lithography, and etching is performed using the resist mask to form a plurality of gate electrodes 14 from the polysilicon film. Next, a silicon dioxide film with a thickness of 10 nm is deposited on the entire surface of the semiconductor substrate 11, and then, the silicon dioxide film is fully etched back until the semiconductor substrate 11 is exposed in order to form an offset spacer 16 on a side surface of each gate electrode 14. After that, with the use of the gate insulating film 13, the gate electrode 14, and the offset spacer 16 as a mask, arsenic (As⁺) ions are implanted into the semiconductor substrate 11 under the implant conditions that the accelerating voltage is 1.5 keV and the dose is 1×10¹⁵ cm⁻², thereby forming an n-type extension region 17 in an upper portion of the semiconductor substrate 11.

Next, as shown in FIG. 13B, a silicon dioxide film with a thickness of 15 nm and a silicon nitride film with a thickness of 30 nm are sequentially deposited on the semiconductor substrate 11 to cover the gate electrode 14 and the offset spacer 16. Then, the silicon nitride film and the silicon dioxide film are fully etched back until the semiconductor substrate 11 is exposed in order to form a first sidewall 18 from the silicon dioxide film and a second sidewall 19 from the silicon nitride film. After that, As⁺ ions are implanted into the semiconductor substrate 11 under the implant conditions that the accelerating voltage is 15 keV and the dose is 7×10¹⁴ cm⁻², while covering a PMOS region (not shown) with a resist film, and using the gate electrode 14, the offset spacer 16, the first sidewall 18, and the second sidewall 19 as a mask. As a result, an n-type extension region 17 is formed in an upper portion of the semiconductor substrate 11. Then, after removing the resist film by ashing and cleaning, a source/drain diffusion layer 20 is formed in an nMISFET by rapid heat treatment for 10 seconds at a temperature of 1000° C.

Then, as shown in FIG. 13C, a protective film 21 for protecting the non-silicide-formation region B from silicidation reaction is formed in the silicide formation region A, before forming a silicide layer in each of the upper portions of the gate electrode 14 and the source/drain diffusion layer 20. Specifically, a silicon dioxide film with a thickness of 23 nm is deposited on the semiconductor substrate 11. Then, a resist film 22 covering the non-silicide-formation region B is patterned on the deposited silicon dioxide film, and the silicon dioxide film in the silicide formation region A is removed by wet etching using the patterned resist film as a mask to form the protective film 21 from the silicon dioxide film.

Next, as shown in FIG. 14A, the resist film 22 is removed by ashing and cleaning. Then, in the silicide formation region A, the second sidewall 19 made of silicon nitride is removed by wet etching.

After that, as shown in FIG. 14B, a native oxide film formed on the upper surface of the source/drain diffusion layer 20 in the silicide formation region A is removed by, for example, wet etching using dilute hydrofluoric acid. Then, a nickel (Ni) film with a thickness of 5 nm is deposited on the semiconductor substrate 11 by sputtering. Next, a nickel silicide layer 23 is formed in each of the upper portions of the gate electrode 14 and the source/drain diffusion layer 20 in the silicide formation region A by rapid heat treatment. At this time, in the non-silicide-formation region B, since the protective film 21 is formed, the nickel silicide layer 23 is not formed in each of the gate electrode 14 and the source/drain diffusion layer 20. Then, an unreacted Ni film remaining in the non-silicide-formation region B is removed by cleaning with sulfuric peroxide mixture (SPM) and ammonium peroxide mixture (APM).

Then, as shown in FIG. 14C, a stress liner film 24 having a thickness of 50 nm and made of silicon nitride causing predetermined stress is deposited on the entire surface of the semiconductor substrate 11. Next, an interlayer insulating film 25 made of silicon dioxide is deposited on the entire surface of the semiconductor substrate 11. After that, the upper surface of the deposited interlayer insulating film 25 is smoothed by chemical mechanical polishing (CMP).

### SUMMARY

However, in the above-described manufacturing method of the conventional semiconductor device, the thickness of the protective film 21 is unignorable with miniaturization of the transistor.

Specifically, as shown in FIG. 15A, the space between the gate electrodes 14 is filled with the protective film 21 in a pattern region W1 in which the distance between the gate electrodes 14 is small. Thus, a thickness d3 of the protective film 21 deposited in the pattern region W1 is greater than a thickness d4 of the deposited protective film 21 deposited in a pattern region W2 in which the distance between the gate electrodes 14 is large. For example, as shown in FIG. 15B, when the protective film 21 in the silicide formation region is removed by dry etching, the protective film 21 of a transistor in the pattern region W2 with large gate spacing is overetched to excessively etch the semiconductor substrate 11 which is an underlying layer, while removing the protective film 21 in the pattern region W1 with small gate spacing. This causes junction leakage.

In order to reduce occurrence of the junction leakage, as shown in FIG. 15C, a method of removing the protective film 21 by wet etching is preferable. However, although wet etching reduces excessive etching of the semiconductor substrate 11, an end of the first sidewall 18, which is a spacer (hereinafter referred to as “L-shaped spacer”) facing the pattern region W2 with large gate spacing and having, for example, an L-shaped cross-section, is etched, and has a recess in a gate channel direction. In this state, a silicide layer is formed to in a position close to a channel, thereby causing junction leakage.

In order to reduce etching of an end of an L-shaped spacer, an L-shaped spacer made of a high-k material with high etching resistance is suggested as shown in Japanese Patent Publication No. 2005-150713. Specifically, the material may be, aluminum oxide (Al₂O₃), hafnium dioxide (HfO₂), tantalum oxide (Ta₂O₃), etc., which actually have high resistance to hydrofluoric acid, thereby reducing etching.

However, since these materials have high etching resistance, it is difficult to selectively remove the materials when forming an L-shaped spacer in a silicide formation region. Although Japanese Patent Publication No. 2005-150713 suggests a process for facilitating removal of such materials by ion implantation etc., the end of the L-shaped spacer may be etched depending on the amount of overetching in wet etching.

When using the materials with high dielectric constants, capacitance between gates increases to reduce operation speed of a miniaturized transistor.

In view of the problems, it is an objective of the present disclosure to reduce problems such as junction leakage in silicide formation in a miniaturized transistor without increasing capacitance between gates and without etching an end of an L-shaped spacer.

In order to achieve the objective, in a semiconductor device and a manufacturing method of the device according to the present disclosure, a first sidewall (e.g., an L-shaped spacer) in a silicide formation region is resistant to an etching material (an etchant or etching gas) used for etching a third sidewall formed on a side surface of a second sidewall (e.g., an L-shaped spacer) in a non-silicide-formation region.

Specifically, a semiconductor device according to the present disclosure includes a first transistor including a first gate electrode formed on a semiconductor region with a first gate insulating film interposed therebetween, a first sidewall formed on a side surface of the first gate electrode, first source/drain regions, each formed in an upper portion of the semiconductor region at a side of the first gate electrode; and a second transistor including a second gate electrode formed on the semiconductor region with a second gate insulating film interposed therebetween, a second sidewall formed on a side surface of the second gate electrode, a third sidewall formed outside the second sidewall, and second source/drain regions, each formed in an upper portion of the semiconductor region at a side of the second gate electrode. A silicide layer is formed in each of upper portions of the first gate electrode and the first source/drain regions in the first transistor. No silicide layer is formed in each of upper portions of the second gate electrode and the second source/drain regions in the second transistor. The first sidewall is resistant to an etching material used for etching the third sidewall.

In the semiconductor device according to the present disclosure, the sidewall, which is made of a material forming the third sidewall of the second transistor formed in the non-silicide-formation region, is formed on the side surface of the first sidewall of the first transistor formed in the silicide formation region during manufacture. Then, the first sidewall is resistant to the etching material used for etching the third sidewall. Therefore, occurrence of junction leakage can be reduced since an end of the first sidewall is hardly etched when exposing the first sidewall in the silicide formation region. Also, since there is no need to use a material with a high dielectric constant for the first sidewall, the capacitance between gates does not increase, thereby preventing the operation speed of a miniaturized transistor from decreasing.

In the semiconductor device of the present disclosure, the first sidewall and the second sidewall may be made of silicon oxide. The third sidewall may be made of silicon nitride.

In the semiconductor device of the present disclosure, the first sidewall and the second sidewall may be made of silicon nitride. The third sidewall may be made of silicon oxide.

In the semiconductor device of the present disclosure, a first protective film and a second protective film may be sequentially formed on the second transistor so that the first protective film is closer to the semiconductor region than the second protective film. The first protective film may have an etching rate equal to or higher than that of the third sidewall with respect to the etching material. The second protective film may be resistant to the etching material.

In this case, the first protective film may be made of silicon nitride. The second protective film may be made of silicon oxide.

In the semiconductor device of the present disclosure, a third protective film may be formed on the second transistor. The third protective film may have an etching rate equal to that of the third sidewall with respect to the etching material.

In this case, the third protective film may be made of silicon oxide.

The semiconductor device of the present disclosure may further include a liner film formed to cover the first transistor and the second transistor.

A first manufacturing method of a semiconductor device according to the present disclosure includes the steps of: (a) sequentially forming a first gate insulating film and a first gate electrode in a silicide formation region on a semiconductor region, and sequentially forming a second gate insulating film and a second gate electrode in a non-silicide-formation region on the semiconductor region; (b) sequentially forming a first sidewall on a side surface of the first gate insulating film and a side surface of the first gate electrode, and a second sidewall on a side surface of the second gate insulating film and a side surface of the second gate electrode; (c) after the step (b), forming first source/drain regions, each formed in an upper portion of the semiconductor region at a side of the first gate electrode, and forming second source/drain regions, each formed in an upper portion of the semiconductor region at a side of the second gate electrode; (d) after the step (c), sequentially forming a first protective film and a second protective film above the semiconductor region from the silicide formation region to the non-silicide-formation region; (e) selectively removing the second protective film included in the silicide formation region; (f) removing the first protective film and the second sidewall in the silicide formation region using the second protective film remaining in the non-silicide-formation region as a mask; and (g) forming a metal silicide layer in each of upper portions of the first gate electrode and the first source/drain regions by forming a metal film on the semiconductor region and heating the formed metal film, while forming no metal silicide layer in each of upper portions of the second gate electrode and the second source/drain regions.

In the first manufacturing method, after the step (c), the first protective film and the second protective film are sequentially formed on the semiconductor region from the silicide formation region to the non-silicide-formation region. Then, the second protective film included in the silicide formation region is selectively removed, and the first protective film and the second sidewall in the silicide formation region is removed using the second protective film remaining in the non-silicide-formation region as the mask. This prevents an end of the first sidewall from being etched when removing the second sidewall and exposing the first sidewall, thereby reducing occurrence of junction leakage. Also, since there is no need to use a material with a high dielectric constant for the first sidewall, the capacitance between gates does not increase. In addition, the protective film separating the silicide formation region from the non-silicide-formation region can be formed without considering the distance between the gate electrodes, thereby reducing a cell size of a transistor.

The first manufacturing method may further include the step of (h) after the step (g), forming a liner film from the silicide formation region to the non-silicide-formation region.

The first manufacturing method may further include the step of (i) after the step (g), removing the second protective film and the first protective film in the non-silicide-formation region.

In the first manufacturing method, the first sidewall and the second protective film may be made of silicon oxide, and the second sidewall and the first protective film may be made of silicon nitride.

A second manufacturing method of a semiconductor device according to the present disclosure includes the steps of: (a) sequentially forming a first gate insulating film and a first gate electrode in a silicide formation region on a semiconductor region, and sequentially forming a second gate insulating film and a second gate electrode in a non-silicide-formation region on the semiconductor region; (b) sequentially forming a first sidewall on a side surface of the first gate insulating film and a side surface of the first gate electrode, and a second sidewall on a side surface of the second gate insulating film and a side surface of the second gate electrode; (c) after the step (b), forming first source/drain regions, each formed in an upper portion of the semiconductor region at a side of the first gate electrode, and forming second source/drain regions, each formed in an upper portion of the semiconductor region at a side of the second gate electrode; (d) after the step (c), forming a protective film above the semiconductor region from the silicide formation region to the non-silicide-formation region; (e) selectively removing the protective film and the second sidewall included in the silicide formation region; and (f) forming a metal silicide layer in each of upper portions of the first gate electrode and the first source/drain regions by forming a metal film on the semiconductor region and heating the formed metal film.

In the second manufacturing method, after the step (c), the protective film is formed above the semiconductor region from the silicide formation region to the non-silicide-formation region. Then, the protective film and the second sidewall included in the silicide formation region are selectively removed. This prevents an end of the first sidewall from being etched when removing the second sidewall and exposing the first sidewall, thereby reducing occurrence of junction leakage. Also, since there is no need to use a material with a high dielectric constant for the first sidewall, the capacitance between gates does not increase. In addition, the protective film separating the silicide formation region from the non-silicide-formation region can be formed without considering the distance between the gate electrodes, thereby reducing a cell size of a transistor.

The second manufacturing method may further include the step of (g) after the step (f), forming a liner film from the silicide formation region to the non-silicide-formation region.

The second manufacturing method may further include the step of (h) after the step (f), removing the protective film in the non-silicide-formation region.

In the second manufacturing method, the first sidewall may be made of silicon nitride. The second sidewall and the protective film may be made of silicon oxide.

In the semiconductor device and the manufacturing method of the device according to the present disclosure, when forming the protective film separating the silicide formation region from the non-silicide-formation region, the end of the first sidewall (e.g., the L-shaped spacer) for separating the gate electrode from the silicide layer is not etched. This reduces problems such as junction leakage. In addition, a protective film separating the silicide formation region from the non-silicide-formation region can be formed without considering the distance between gate electrodes, thereby reducing a cell size of a transistor.

### BRIEF DESCRIPTION OF THE DRAWINGS

FIG. 1 is a cross-sectional view illustrating a main part of a semiconductor device according to a first example embodiment of the present disclosure.

FIGS. 2A-2C are cross-sectional views illustrating steps of a manufacturing method of the semiconductor device according to the first example embodiment.

FIGS. 3A-3C are cross-sectional views illustrating steps of the manufacturing method of the semiconductor device according to the first example embodiment.

FIGS. 4A-4C are cross-sectional views illustrating steps of the manufacturing method of the semiconductor device according to the first example embodiment.

FIGS. 5A and 5B are schematic cross-sectional views illustrating advantages of the manufacturing method of the semiconductor device according to the first example embodiment.

FIGS. 6A and 6B are schematic cross-sectional views illustrating advantages of the manufacturing method of the semiconductor device according to the first example embodiment.

FIG. 7 is a schematic cross-sectional view illustrating problems in a manufacturing method of a conventional semiconductor device.

FIG. 8 is a schematic cross-sectional view illustrating problems in a manufacturing method of the conventional semiconductor device.

FIG. 9 is a cross-sectional view illustrating a main part of a semiconductor device according to a second example embodiment of the present disclosure.

FIGS. 10A-10C are cross-sectional views illustrating steps of a manufacturing method of the semiconductor device according to the second example embodiment.

FIGS. 11A-11C are cross-sectional views illustrating steps of the manufacturing method of the semiconductor device according to the second example embodiment.

FIGS. 12A and 12B are cross-sectional views illustrating steps of the manufacturing method of the semiconductor device according to the second example embodiment.

FIGS. 13A-13C are cross-sectional views illustrating steps of a manufacturing method of a conventional semiconductor device.

FIGS. 14A-14C are cross-sectional views illustrating steps of a manufacturing method of the conventional semiconductor device.

FIGS. 15A-15C are schematic cross-sectional views illustrating problems in a manufacturing method of the conventional semiconductor device.

### DETAILED DESCRIPTION

### First Example Embodiment

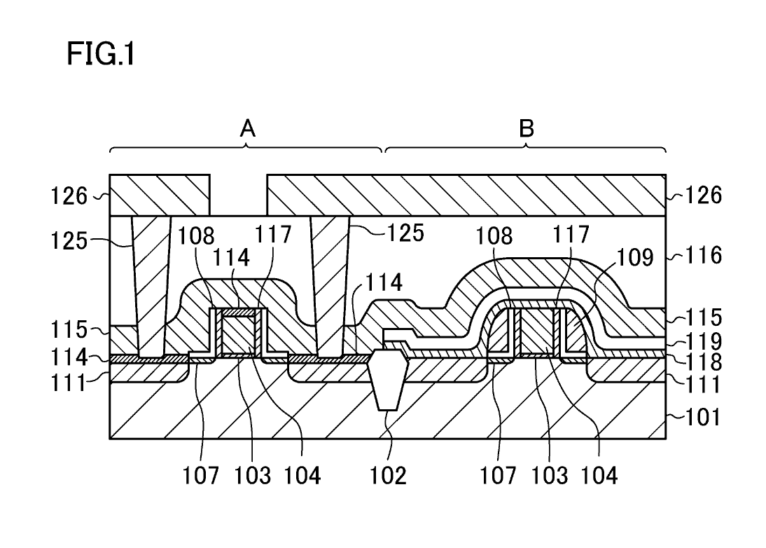

A semiconductor device according to a first example embodiment of the present disclosure will be described below with reference to FIG. 1.

As shown in FIG. 1, in the semiconductor device according to the first example embodiment, a semiconductor substrate (a semiconductor region) 101 made of, for example, silicon (Si) is divided into a silicide formation region A and a non-silicide-formation region B by a shallow trench isolation (STI) region 102.

First, the silicide formation region A will be described.

A first transistor formed in the silicide formation region A includes a gate insulating film 103 formed on the semiconductor substrate 101, a gate electrode 104 formed on the gate insulating film 103, an offset spacer 117 formed on side surfaces of the gate insulating film 103 and the gate electrode 104, and a first sidewall 108 each of which is formed on the outer surface of the offset spacer 117 and having an L-shaped cross-section. The offset spacer 117 is made of silicon nitride (SiN) and the first sidewall 108 is made of silicon dioxide (SiO₂).

An n-type extension region 107 is formed in the semiconductor substrate 101 below the first sidewall 108. An n-type source/drain diffusion layer 111 having a greater junction depth than the extension region 107 is formed in the semiconductor substrate 101 outside the extension region 107. A nickel silicide layer 114 is formed in each of the upper portions of the gate electrode 104 and the source/drain diffusion layer 111.

A stress liner film 115 made of silicon nitride and an interlayer insulating film 116 made of silicon dioxide are sequentially formed on the semiconductor substrate 101 to cover the gate electrode 104. Contacts 125, which are in contact with the nickel silicide layer 114 and made of tungsten (W) etc., are formed in the interlayer insulating film 116 having a smoothed upper surface above the source/drain diffusion layer 111. An interconnect 126 electrically connected to the contacts 125 and made of metal such as copper (Cu) is formed on the interlayer insulating film 116.

Then, the non-silicide-formation region B will be described.

Differences from the transistor of the silicide formation region A will be described.

The differences are as follows. A second sidewall 109 made of silicon nitride is formed outside the first sidewall 108 of the gate electrode 104. The nickel silicide layer 114 is not formed in each of the upper portions of the gate electrode 104 and the source/drain diffusion layer 111. A first protective film 118 made of silicon nitride and a second protective film 119 made of silicon dioxide are sequentially formed from bottom between the semiconductor substrate 101 and the stress liner film 115.

In the first example embodiment, the first sidewall 108 made of silicon dioxide in the silicide formation region A is resistant to an etching material (an etchant or etching gas) used for etching the second sidewall 109 made of silicon nitride in the non-silicide-formation region B. While FIG. 1 shows only nMISFETs as transistors formed in the silicide formation region A and the non-silicide-formation region B, pMISFETs are also formed on the substrate.

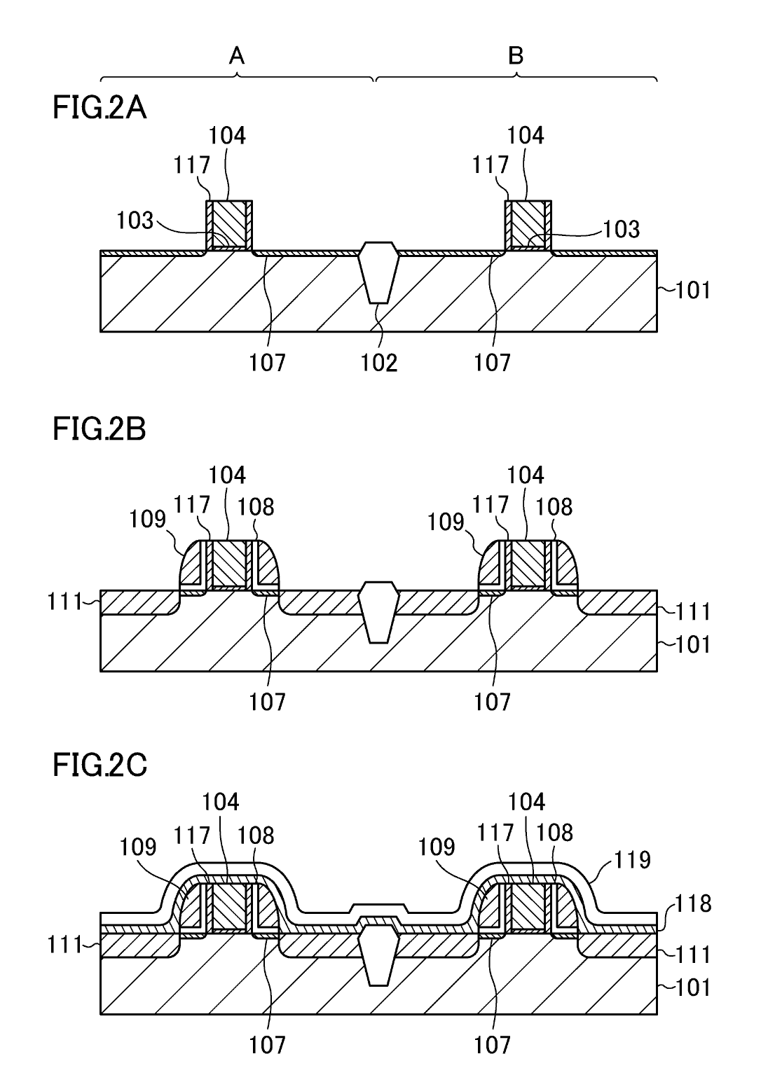

A manufacturing method of the semiconductor device with the above-described structure will be described below with reference to FIGS. 2A-2C, 3A-3C, and 4A-4C.

First, as shown in FIG. 2A, the STI region 102a having a thickness of 300 nm and made of silicon dioxide is selectively formed in the upper portion of the semiconductor substrate 101 made of silicon. Then, the gate insulating film 103 having a thickness of 2 nm and made of silicon dioxide, and a polysilicon film having a thickness of 100 nm are sequentially formed. The gate insulating film 103 may be formed by thermal oxidation, chemical vapor deposition (CVD), atomic layer deposition (ALD), etc. The polysilicon film may be formed by CVD etc. After that, a resist mask is patterned by lithography, and etching with the resist mask is performed to form multiple ones of the gate electrodes 104 from the polysilicon film. Then, a silicon nitride film with a thickness of 10 nm is deposited on the entire surface of the semiconductor substrate 101 by CVD etc. After that, a full etch-back is performed until the semiconductor substrate 101 is exposed in order to form the offset spacer 117 made of silicon nitride on each side surface of the gate electrode 104. Next, arsenic (As⁺) ions are implanted into the semiconductor substrate 101 under the implant conditions that the accelerating voltage is 1.5 keV and the dose is 1×10¹⁵ cm⁻² using the gate insulating film 103, the gate electrode 104, and the offset spacer 117 as a mask, thereby forming the extension region 107 in an upper portion of the semiconductor substrate 101.

Next, as shown in FIG. 2B, a silicon dioxide film with a thickness of 15 nm and a silicon nitride film with a thickness of 30 nm are sequentially deposited on the semiconductor substrate 101 by CVD to cover the gate electrode 104 and the offset spacer 117. Then, the deposited silicon nitride film and the deposited silicon dioxide film are fully etched back until the semiconductor substrate 101 is exposed in order to form the first sidewall 108 with an L-shaped cross-section from the silicon dioxide film, and the second sidewall 109 made of silicon nitride outside the first sidewall 108. After that, As⁺ ions are implanted into the semiconductor substrate 101 under the implant conditions that the accelerating voltage is 15 keV and the dose is 7×10¹⁴ cm⁻², while covering a PMOS region (not shown) with a resist film, and using the gate electrode 104, the offset spacer 117, the first sidewall 108, and the second sidewall 109 as a mask. Then, after removing the resist film by ashing and cleaning, the source/drain diffusion layer 111 is formed in an nMISFET by rapid heat treatment for 10 seconds at a temperature of 1000° C.

Then, as shown in FIG. 2C, the first protective film 118 and the second protective film 119 for protecting the non-silicide-formation region B from silicidation reaction are formed in the silicide formation region A, before forming a silicide layer in each of the upper portions of the gate electrode 104 and the source/drain diffusion layer 111. Specifically, a silicon nitride film with a thickness of 8 nm and a silicon dioxide film with a thickness of 15 nm are sequentially deposited on the semiconductor substrate 101 by ALD.

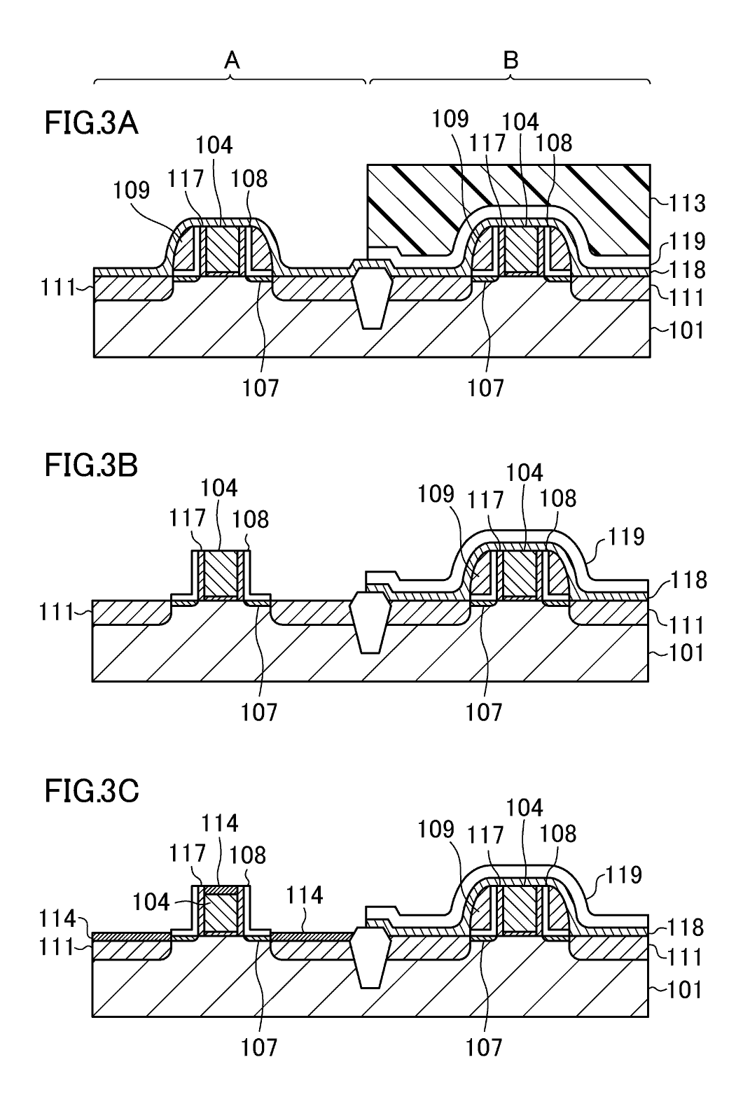

After that, as shown in FIG. 3A, a resist film 113 with an opening pattern covering the non-silicide-formation region B and exposing the silicide formation region A is formed by lithography. Then, the silicon dioxide film is wet etched using the resist film 113 as an etching mask to form the second protective film 119 made of silicon dioxide.

The etchant used for wet etching the silicon dioxide when forming the second protective film 119 for protection from silicidation reaction by etching may be for example, dilute hydrofluoric acid, where hydrogen fluoride (HF):water (H₂O)=1:40. At this time, as shown in FIG. 5A, in a region W1 in which the distance between the gate electrodes 104 is smaller than the total thickness of the first protective film 118 and the second protective film 119, a thickness d1 of the second protective film 119 is greater than a thickness d2, which is 15 nm, of the second protective film 119 in a region W2, in which the distance between the gate electrodes 104 is smaller than the total thickness of the first protective film 118 and the second protective film 119. Therefore, sufficient overetching is needed to completely remove the second protective film 119 made of silicon dioxide.

In the first example embodiment, as shown in FIG. 5A, the first protective film 118 made of silicon nitride having high selectivity for the dilute hydrofluoric acid is formed under the second protective film 119. This prevents the first sidewall 108 made of silicon dioxide and covered by the first protective film 118 from being etched.

Then, as shown in FIG. 3B, ashing and cleaning are performed to remove the resist film 113 formed in the non-silicide-formation region B. After that, the first protective film 118 made of silicon nitride and the second sidewall 109 made of silicon nitride, which are exposed from the silicide formation region A, are removed by wet etching using the second protective film 119 as a mask. As a result, in the non-silicide-formation region B, the first protective film 118 made of silicon nitride is formed under the second protective film 119.

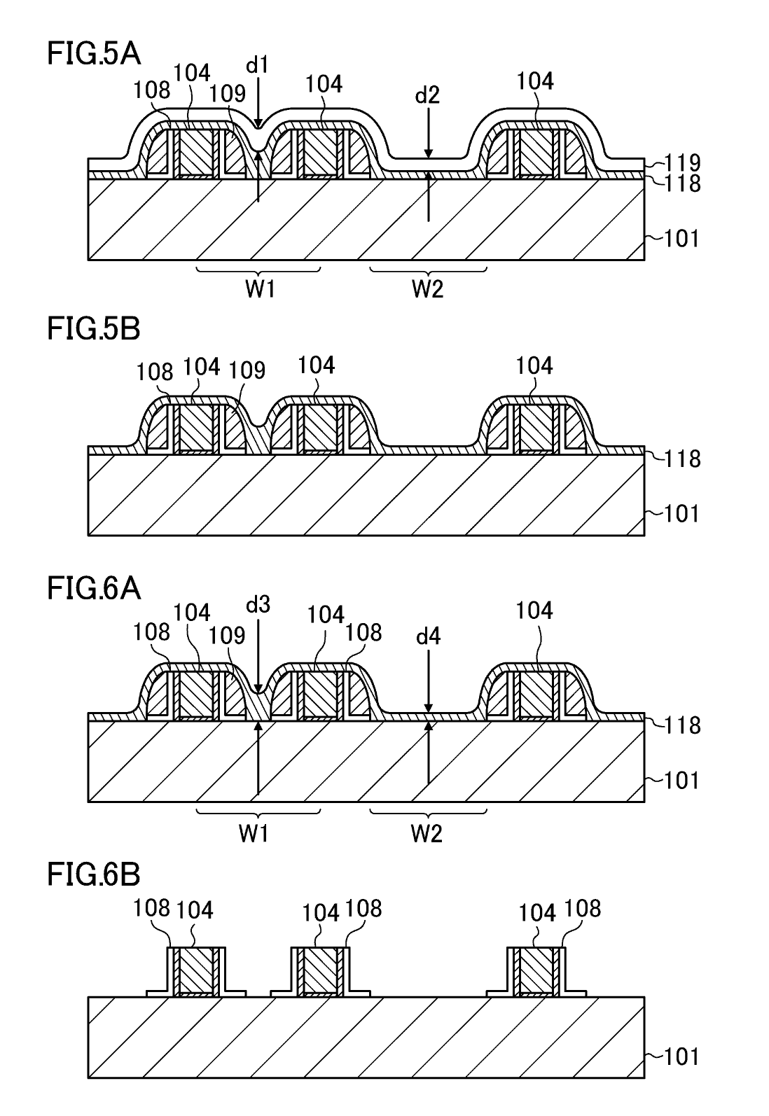

The etchant of silicon nitride used for forming the first protective film 118 for protection from silicidation reaction and removing the second sidewall 109 may be for example, the solution of phosphoric acid (H₃PO₄) (so-called hot phosphoric acid) at a temperature of 130° C. At this time, as shown in FIG. 6A, in a region W1 in which the distance between gate electrodes 104 is smaller than the thickness of the first protective film 118, a thickness d3 of the first protective film 118 is greater than a thickness d4, which is 8 nm, of the first protective film 118 in a region W2 in which the distance gate electrodes 104 is greater than the thickness of the first protective film 118. Therefore, sufficient overetching is needed to completely remove the first protective film 118 made of silicon nitride.

In the first example embodiment, as shown in FIG. 6B, the first sidewall 108 is made of silicon dioxide which has high etching resistance to hot phosphoric acid, and is thus hardly etched. While the etchant (the etching solution) is used in the above-described etching, removal can be performed by isotropic etching with etching gas in place of the etchant.

In the first example embodiment, the second sidewall 109 made of silicon nitride is removed to more largely deform a channel below the gate electrode 104 in following deposition of the stress liner film 115 to increase operation speed of a transistor.

Next, as shown in FIG. 3C, a native oxide film (not shown) formed on the upper surface of the source/drain diffusion layer 111 is removed in the silicide formation region A by, for example, wet etching using dilute hydrofluoric acid. Then, a nickel (Ni) film with a thickness of 5 nm is deposited on the semiconductor substrate 101 by sputtering. After that, the nickel silicide layer 114 is formed by rapid heat treatment, in each of the upper portions of the gate electrode 104 and the source/drain diffusion layer 111 in the silicide formation region A. At this time, in the non-silicide-formation region B, since the first protective film 118 and the second protective film 119 are formed, the nickel silicide layer 114 is not formed in each of the gate electrode 104 and the source/drain diffusion layer 111. Then, an unreacted Ni film remaining in the non-silicide-formation region B is removed by cleaning with sulfuric peroxide mixture (SPM) and ammonium peroxide mixture (APM).

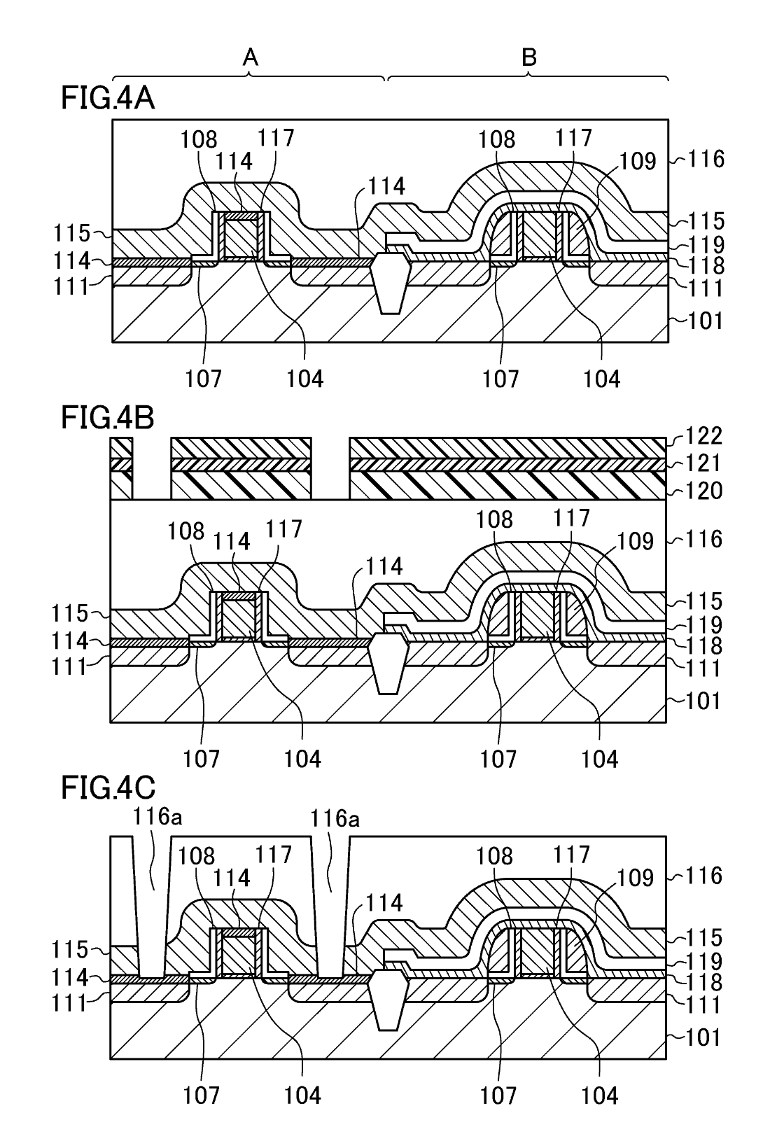

Then, as shown in FIG. 4A, the stress liner film 115, which has a thickness of 50 nm, is made of silicon nitride causing predetermined stress, and applies the stress to the first and second transistors, is deposited on the entire surface of the semiconductor substrate 101. After that, the interlayer insulating film 116 made of silicon dioxide is deposited on the entire surface of the semiconductor substrate 101, and the upper surface of the deposited interlayer insulating film 116 is smoothed by chemical mechanical polishing (CMP).

Next, as shown in FIG. 4B, multilayer resist formed by sequentially laminating a lower resist film 120, an intermediate resist film 121, and an upper resist film 122, is provided on the smoothed interlayer insulating film 116. Then, an opening pattern for forming a contact is provided in the multilayer resist by lithography.

After that, as shown in FIG. 4C, the interlayer insulating film 116 is etched using the multilayer resist provided with the opening pattern as a mask, until the underlying stress liner film 115 is exposed. Then, the exposed stress liner film 115 is further etched to form contact holes 116a in the interlayer insulating film 116 and the stress liner film 115.

In this example embodiment, the patterning of the multilayer resist is performed by developing the upper resist film 122, and then dry etching the intermediate resist film 121 and the lower resist film 120. As an example, the intermediate resist film 121 is dry etched using CF₄/CHF₃=200/40 [ml/min (under standard conditions)] as etching gas, pressure of 13 Pa in an etching atmosphere, etching equipment of dual frequency parallel plate reactive ion etching (ME), an upper electrode of 600 W and a lower electrode of 300 W as RF power, and a substrate temperature of 20° C.

Then, as an example, the lower resist film 120 is dry etched using the upper resist film 122 and the intermediate resist film 121 formed by dry etching as a mask, CO/O₂/Ar=100/50/500 [ml/min (under standard conditions)] as etching gas, pressure of 2 Pa in an etching atmosphere, etching equipment of dual frequency parallel plate ME, an upper electrode of 1500 W and a lower electrode of 300 W as RF power, and a substrate temperature of 20° C.

As an example, the interlayer insulating film 116 made of silicon dioxide is dry etched using C₄F₆/Ar/O₂=20/1500/18 [ml/min (under standard conditions)] as etching gas, pressure of 4 Pa in an etching atmosphere, etching equipment of dual frequency parallel plate RIE, an upper electrode of 1000 W and a lower electrode of 1500 W as RF power, and a substrate temperature of 20° C.

As an example, the stress liner film made of silicon nitride is dry etched using CHF₃/Ar/O₂=20/800/15 [ml/min (under standard conditions)] as etching gas, pressure of 3 Pa in an etching atmosphere, etching equipment of dual frequency parallel plate ME, an upper electrode of 1000 W and a lower electrode of 300 W as RF power, and a substrate temperature of 20° C.

Then, as shown in FIG. 1, the contact holes 116a formed in the interlayer insulating film 116 is filled with tungsten etc. to form the contacts 125. Next, the interconnect 126 is selectively formed on the interlayer insulating film 116 to be connected to the contacts 125 to obtain a semiconductor device. An adhesive layer or a barrier layer may be formed inside each of the contact holes 116a.

In the manufacturing method according to the first example embodiment, as shown in FIG. 3B, when removing the first protective film 118 included in the silicide formation region A, the second sidewall 109 is also removed at the same time. With this feature, when the thickness of the first protective film 118 varies depending on the density of the gate electrode 104, side-etch does not occur at a lower end of the first sidewall 108 even by increasing the amount of overetching the first protective film 118 to remove the first protective film 118, since etching selectivity is provided between the first protective film and the first sidewall 108.

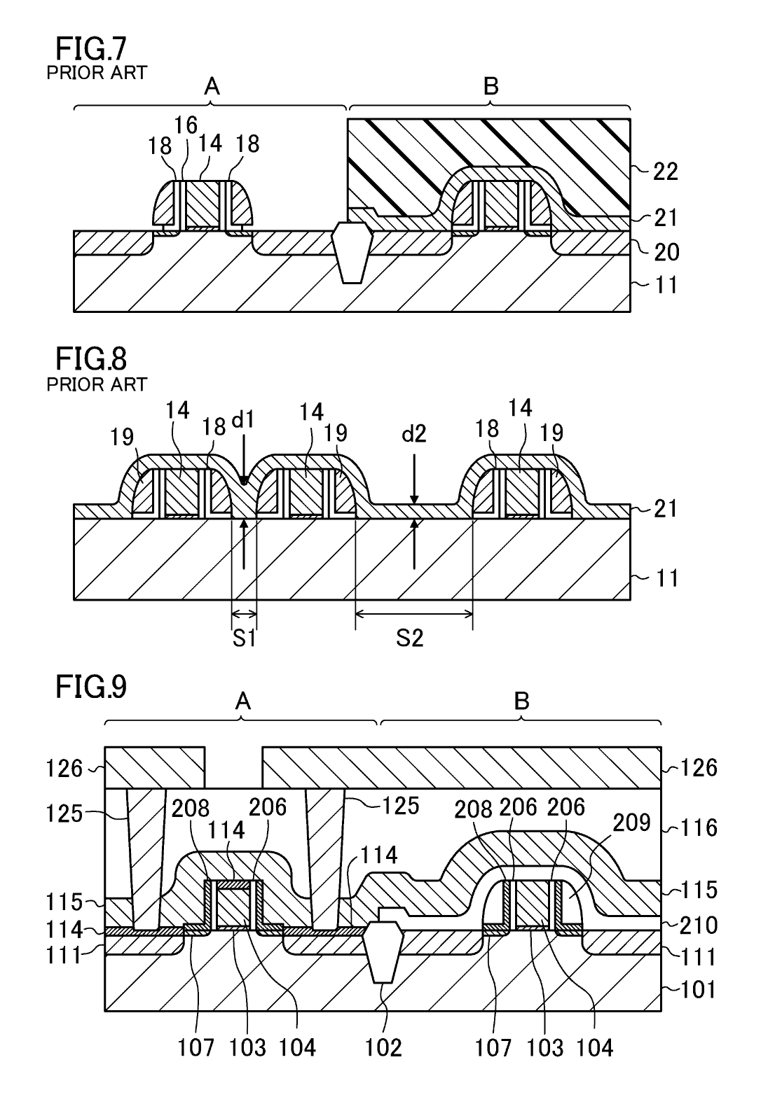

Specifically, in the step shown in FIG. 3B, the first sidewall 108 made of silicon dioxide is resistant to the hot phosphoric acid, and thus remains unetched when removing the first protective film 118 included in the silicide formation region. Thus, as in the conventional example shown in FIG. 7, no recess occurs at a lower end of the first sidewall 18 made of silicon dioxide. In the first example embodiment, since the nickel silicide layer 114 is formed outside the first sidewall 108 maintaining its predetermined form, and is thus not formed near a gate channel or in an upper portion of the extension region 107. That is, since the bottom surface of the nickel silicide layer 114 is surrounded by the source/drain diffusion layer 111, leakage currents occurring between the nickel silicide layer 114 and the substrate region of the semiconductor substrate 101 can be reduced.

As such, in the first example embodiment, the first protective film 118 is also removed when removing the second sidewall 109 included in the silicide formation region A. Thus, even when the distance between the gate electrodes 104 is small, i.e., the distance between the second sidewalls 109 is small, and the space between the second sidewalls 109 is filled with the first protective film 118 and the second protective film 119, the first protective film 118 and the second protective film 119 can be removed without etching the first sidewall 108. Therefore, in the first example embodiment, the distance between the second sidewalls 109 (i.e., between the gate electrodes 104) and a cell size of a transistor can be reduced, thereby reducing the area of a chip.

This advantage is more effectively provided by a miniaturized transistor in which a distance between gate electrodes is small. That is, in FIG. 8, as in a conventional example, assume that the thickness of the protective film 21 is d, and the protective film 21 provides 100% coverage of the second sidewall 19. When a distance S2 is sufficiently larger than the thickness d of the protective film 21 (S2>>d) as indicated by the distance S2, the thickness d2 of the protective film 21 between the gate electrodes 14 is equal to the thickness d (d2=d). On the other hand, as indicated by a distance S1, when the distance S1 is smaller than the doubled value of the thickness of the protective film 21 (S1<2d), the thickness d1 of the protective film 21 between the gate electrodes 14 is greater than the thickness d (d1>d). As a result, in a transistor in which a distance between the gate electrodes 14 is small, the space between the gate electrodes 14 is filled with the protective film 21. Thus, as described above, when removing the protective film 21 in a region in which the distance S1 between the gate electrodes 14 is small, a region in which the distance between the gate electrodes 14 is large is excessively etched to etch the first sidewall 18.

However, in the semiconductor device and the manufacturing method of the device according to the first example embodiment, this problem can be handled only by adding to a conventional manufacturing method, the step of depositing the first protective film 118 made of silicon nitride between the semiconductor substrate 101 and the second protective film 119 made of silicon dioxide. That is, this example embodiment can be easily implemented, provide great process consistency, and sufficiently handle the problem occurring when the distance between the gate electrodes 104 is small.

While in the first example embodiment, the offset spacer 117 is provided between the gate electrode 104 and the first sidewall 108 in FIG. 2B, the offset spacer 117 is not necessarily required. The stress liner film 115 is also not necessarily required.

While in the first example embodiment, an example has been described where the first protective film 118 and the second protective film 119 are the single layers, the present disclosure is not limited thereto. The films may be multilayer films including two or more layers.

While in the first example embodiment, the first protective film 118 and the second protective film 119 are retained in the non-silicide-formation region B as shown in FIG. 1, the present disclosure is not limited thereto. At least one of the protective film 118 or 119 may be removed as necessary.

### Second Example Embodiment

A semiconductor device according to a second example embodiment of the present disclosure will be described below with reference to FIG. 9.

In this example embodiment, only the differences from the first example embodiment will be described. Therefore, the same reference characters as those shown in FIG. 1 are used to represent equivalent elements, and the explanation thereof will be omitted.

As shown in FIG. 9, in the semiconductor device according to the second example embodiment, an offset spacer 206 formed on each side surface of the gate electrode 104 is made of silicon dioxide (SiO₂), and a first sidewall 208 formed outside the offset spacer 206 and having an L-shaped cross-section is made of silicon nitride (SiN). In the non-silicide-formation region B, a second sidewall 209 formed outside the first sidewall 208 and a protective film 210 covering the gate electrode 104 are both made of silicon dioxide.

In the second example embodiment, the first sidewall 208 made of silicon nitride in the silicide formation region A is resistant to an etching material (an etchant or etching gas) used for etching the second sidewall 209 made of silicon dioxide in the non-silicide-formation region B.

While FIG. 9 shows only nMISFETs as transistors formed in the silicide formation region A and the non-silicide-formation region B, pMISFETs are also formed on the substrate.

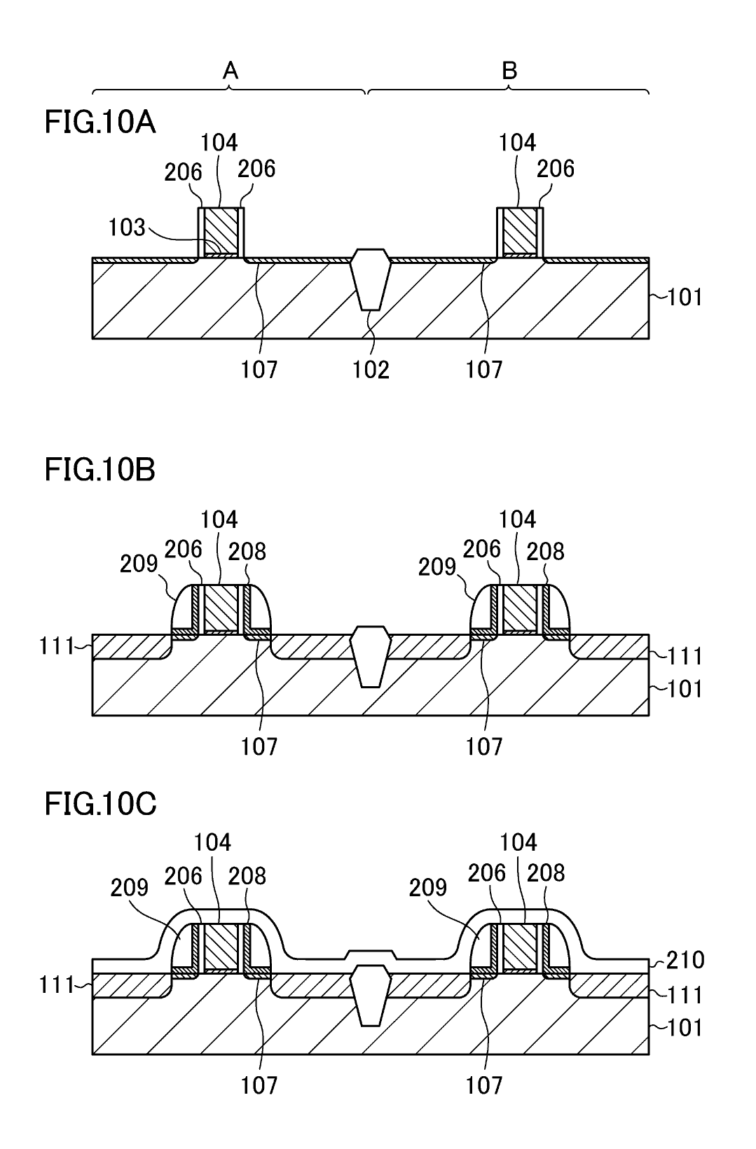

A manufacturing method of the semiconductor device with the above-described structure will be described below with reference to FIGS. 10A-10C, 11A-11C, 12A, and 12B.

First, as shown in FIG. 10A, the STI region 102 having a thickness of 300 nm and made of silicon dioxide is selectively formed in the upper portion of the semiconductor substrate 101 made of silicon. Then, the gate insulating film 103 having a thickness of 2 nm and made of silicon dioxide, and a polysilicon film having a thickness of 100 nm are sequentially formed. The gate insulating film 103 may be formed by thermal oxidation, CVD, ALD, etc. The polysilicon film may be formed by CVD etc. After that, a resist mask is patterned by lithography and etching with the resist mask is performed to form multiple ones of the gate electrode 104 from the polysilicon film. Then, a silicon dioxide film with a thickness of 10 nm is deposited on the entire surface of the semiconductor substrate 101. After that, a full etch-back is performed until the semiconductor substrate 101 is exposed in order to form the offset spacer 206 made of silicon dioxide on each side surface of the gate electrode 104. Next, arsenic (As⁺) ions are implanted into the semiconductor substrate 101 under the implant conditions that the accelerating voltage is 1.5 keV and the dose is 1×10¹⁵ cm⁻², using the gate insulating film 103, the gate electrode 104, and the offset spacer 106 as a mask, thereby forming the extension region 107 in an upper portion of the semiconductor substrate 101.

Next, as shown in FIG. 10B, a silicon nitride film with a thickness of 15 nm and a silicon dioxide film with a thickness of 30 nm are sequentially deposited by CVD to cover the semiconductor substrate 101, the gate electrode 104, and the offset spacer 206. Then, the deposited silicon dioxide film and the deposited silicon nitride film are fully etched back until the semiconductor substrate 101 is exposed in order to form the first sidewall 208 with an L-shaped cross-section from the silicon nitride film, and the second sidewall 209 from made of silicon dioxide outside the first sidewall 208. After that, As⁺ ions are implanted into the semiconductor substrate 101 under the implant conditions that the accelerating voltage is 15 keV and the dose is 7×10¹⁴ cm⁻², while covering a PMOS region (not shown) with a resist film, and using the gate electrode 104, the offset spacer 206, the first sidewall 208, and the second sidewall 209 as a mask. Then, after removing the resist film by ashing and cleaning, the source/drain diffusion layer 111 in an nMISFET is formed by rapid heat treatment for 10 seconds at a temperature of 1000° C.

Then, as shown in FIG. 10C, the protective film 210 for protection from silicidation reaction in the non-silicide-formation region B is formed in the silicide formation region A, before forming a silicide layer in each of the upper portions of the gate electrode 104 and the source/drain diffusion layer 111. Specifically, a silicon dioxide film with a thickness of 23 nm is deposited on the semiconductor substrate 101 by ALD.

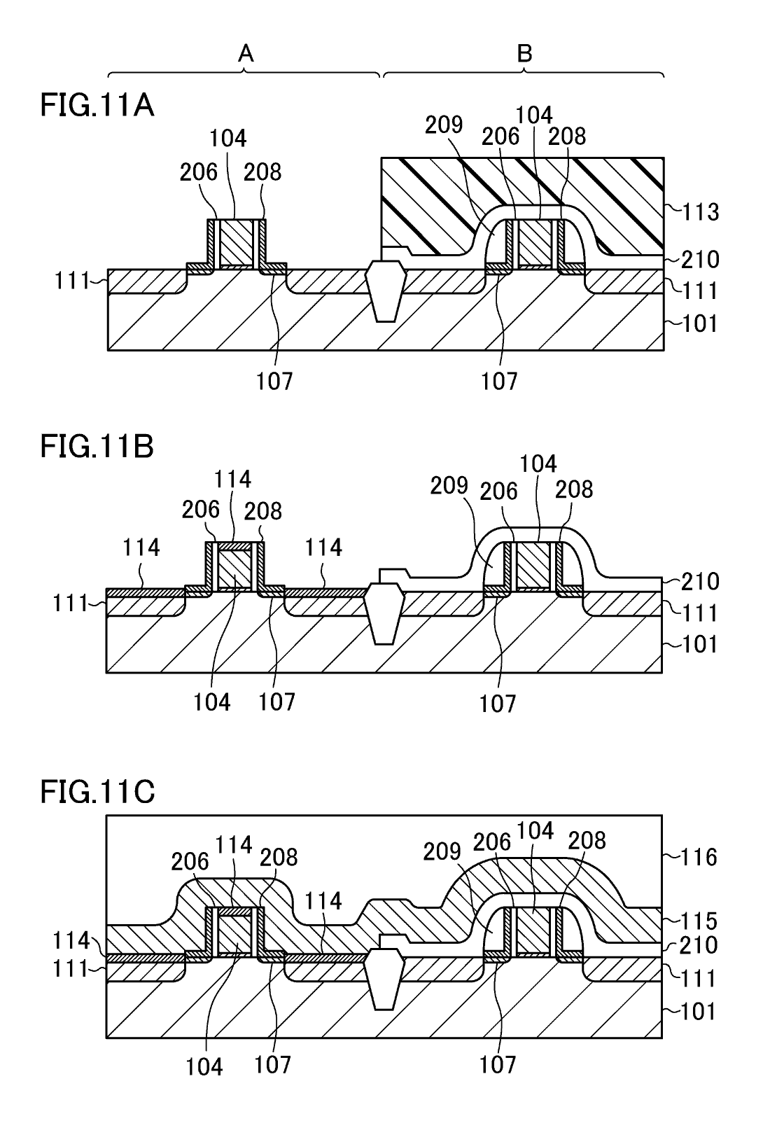

After that, as shown in FIG. 11A, a resist film 113 with an opening pattern covering the non-silicide-formation region B and exposing the silicide formation region A is formed by lithography. Then, the silicon dioxide film is wet etched using the resist film 113 as an etching mask to form the protective film 210 made of silicon dioxide. At the same time, the second sidewall 209 made of silicon dioxide in the silicide formation region A is also removed. As such, the second sidewall 209 is removed to more largely deform a channel below the gate electrode 104 in following deposition of the stress liner film 115 to increase operation speed of a transistor.

The etchant used for wet etching the silicon dioxide when forming the protective film 210 for protection from silicidation reaction by etching may be for example, dilute hydrofluoric acid, where HF:H₂O=1:20. At this time, similar to the description of FIG. 5 in the first example embodiment, the thickness of the protective film 210 in the region, in which the distance between gate electrodes 104 is smaller than the thickness of the protective film 210, is greater than the thickness 23 nm of the protective film 210 in the region in which the distance gate electrodes 104 is greater than the thickness of the protective film 210. Therefore, sufficient overetching is needed to completely remove the protective film 210 made of silicon dioxide.

At this time, in the silicide formation region A, while the second sidewall 209 made of silicon dioxide under the protective film 210 is removed, the first sidewall 208 is hardly etched since it is made of silicon nitride.

While an etching solution is used for etching the protective film 210 and the second sidewall 209, removal can be performed by isotropic etching with etching gas in place of the etchant.

Then, as shown in FIG. 11B, ashing and cleaning are performed to remove the resist film 113 formed in the non-silicide-formation region B. After that, a native oxide film (not shown) formed on the upper surface of the source/drain diffusion layer 111 in the silicide formation region A is removed by, for example, wet etching using dilute hydrofluoric acid. Then, a nickel (Ni) film with a thickness of 5 nm is deposited on the semiconductor substrate 101 by sputtering. Next, the nickel silicide layer 114 is formed in each of the upper portions of the gate electrode 104 and the source/drain diffusion layer 111 in the silicide formation region A by rapid heat treatment. At this time, in the non-silicide-formation region B, since the protective film 210 is formed, the nickel silicide layer 114 is not formed in each of the gate electrode 104 and the source/drain diffusion layer 111. Then, an unreacted Ni film remaining in the non-silicide-formation region B is removed by cleaning with SPM.

Then, as shown in FIG. 11C, the stress liner film 115, which has a thickness of 50 nm, is made of silicon nitride causing predetermined stress, and applies the stress to the first and second transistors, is deposited on the entire surface of the semiconductor substrate 101. After that, the interlayer insulating film 116 made of silicon dioxide is deposited on the entire surface of the semiconductor substrate 101, and the upper surface of the deposited interlayer insulating film 116 is smoothed by CMP.

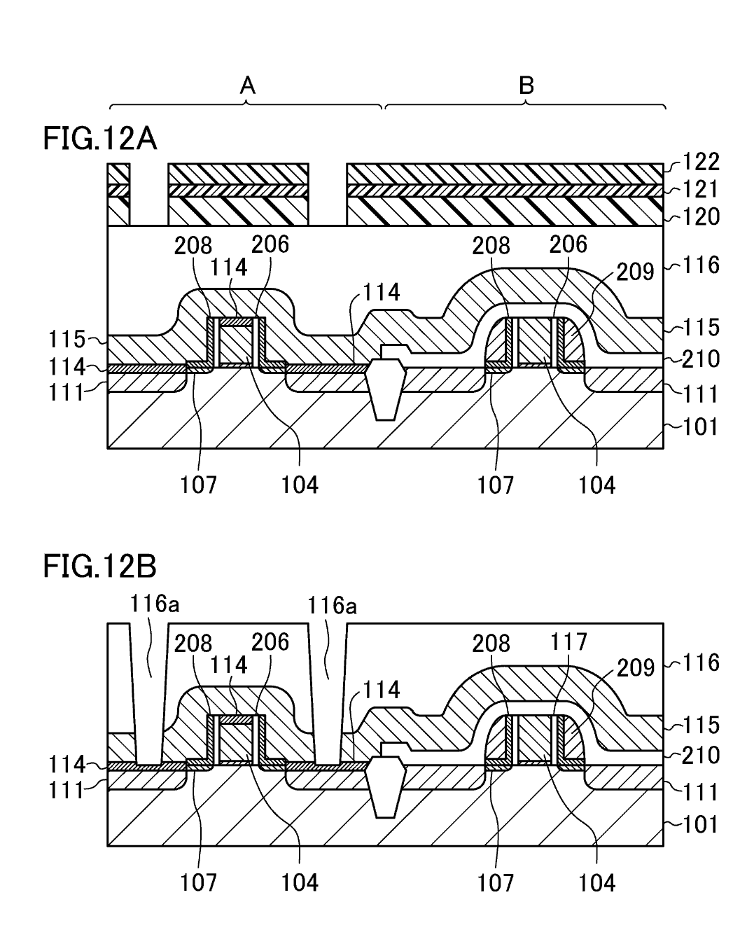

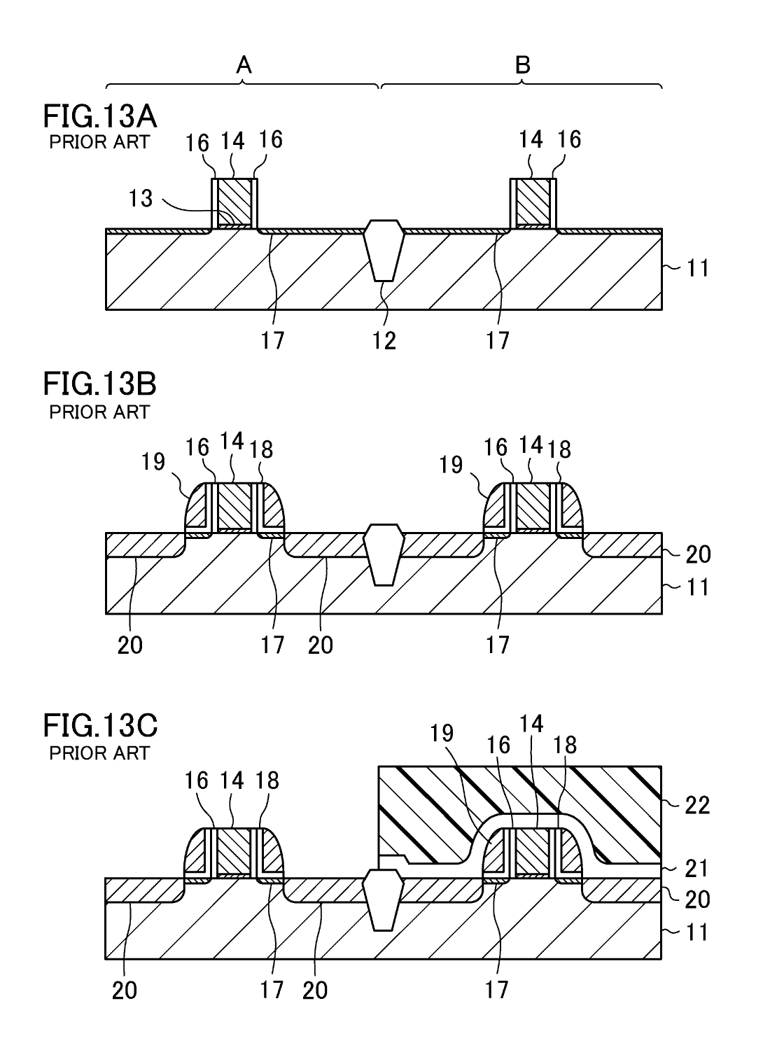

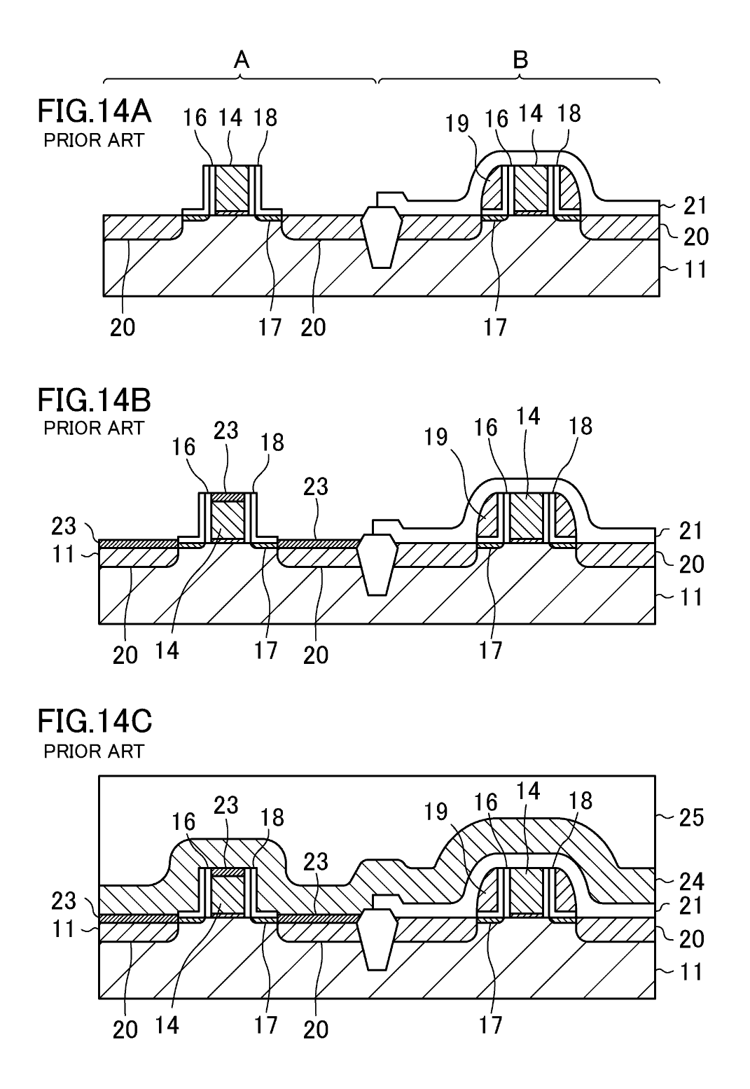

Next, as shown in FIG. 12A, the multilayer resist formed by sequentially laminating the lower resist film 120, the intermediate resist film 121, and the upper resist film 122, is provided on the smoothed interlayer insulating film 116. Then, the opening pattern for forming a contact is provided in the multilayer resist by lithography.

After that, as shown in FIG. 12B, the interlayer insulating film 116 is etched using the multilayer resist provided with the opening pattern as a mask, until the underlying stress liner film 115 is exposed. Then, the exposed stress liner film 115 is further etched to form the contact holes 116a in the interlayer insulating film 116 and the stress liner film 115.

Note that the etching conditions for forming the opening pattern in the multilayer resist and the conditions for dry etching the interlayer insulating film 116 and the stress liner film 115 are similar to those in the first example embodiment.

Then, as shown in FIG. 9, the contact holes 116a formed in the interlayer insulating film 116 is filled with tungsten etc. to form the contacts 125. Next, the interconnect 126 is selectively formed on the interlayer insulating film 116 to be connected to the contacts 125 to obtain a semiconductor device. An adhesive layer or a barrier layer may be formed inside each of the contact holes 116a.

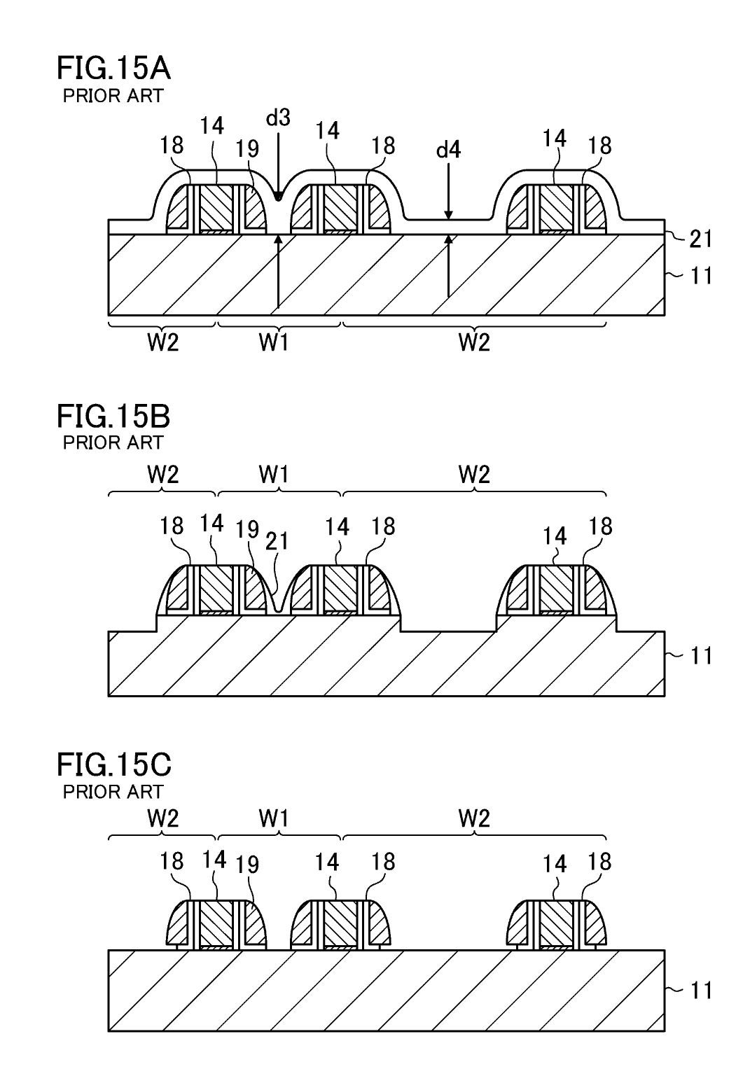

Similar to the first example embodiment, in the manufacturing method according to the second example embodiment, in the step shown in FIG. 11A, the first sidewall 208 made of silicon nitride is resistant to the hot phosphoric acid, and thus remains unetched when removing the protective film 210 and the second sidewall 209 which are included in the silicide formation region A and made of silicon nitride. Thus, as shown in FIGS. 7 and 15C, no recess occurs at a lower end of the first sidewall 208. As a result, since the nickel silicide layer 114 is formed outside the first sidewall 208 maintaining a predetermined form, and is thus not formed near a gate channel or in an upper portion of the extension region 107. That is, since the bottom surface of the nickel silicide layer 114 is surrounded by the source/drain diffusion layer 111, leakage currents occurring between the nickel silicide layer 114 and the substrate region of the semiconductor substrate 101 can be reduced.

In the second example embodiment, the protective film 210 is also removed when removing the second sidewall 209 included in the silicide formation region A. Thus, even when the distance between the gate electrodes 104 is small, i.e., the distance between the second sidewalls 209 is small, and the space between the second sidewalls 209 is filled with the protective film 210, the protective film 210 can be removed without etching the first sidewall 208. Therefore, the distance between the second sidewalls 209 (i.e., between the gate electrodes 104) and a cell size of a transistor can be reduced, thereby reducing the area of a chip.

In the second example embodiment, since the protective film 210 is formed as a single layer, process costs can be reduced as compared to the first example embodiment.

Similar to the first example embodiment, while in the second example embodiment, the offset spacer 206 is provided between the gate electrode 104 and the first sidewall 208 in FIG. 10B, the offset spacer 206 is not necessarily required. The stress liner film 115 is also not necessarily required.

While in the second example embodiment, the protective film 210 is retained in the non-silicide-formation region B as shown in FIG. 9, the present disclosure is not limited thereto. The protective film 210 may be removed as necessary.

While in the first and second example embodiments, an example has been described where a first sidewall has an L-shaped cross-section, the present disclosure is not limited thereto. The sidewall may be in any shape, as long as it faces a side surface of a gate electrode and is in contact with the substrate.

In the semiconductor device and the manufacturing method of the device according to the present disclosure, in silicide formation in a miniaturized transistor, capacitance between gates does not increase, and an end of an L-shaped spacer is prevented from being etched, thereby reducing problems such as junction leakage etc. Therefore, the present disclosure is useful as semiconductor device etc. including a silicide layer in a source/drain region of a transistor.

What is claimed is:

1. A semiconductor device comprising:
a first transistor including
a first gate electrode formed on a semiconductor region with a first gate insulating film interposed therebetween,
a first sidewall formed on a side surface of the first gate electrode,
first source/drain regions, each formed in an upper portion of the semiconductor region at a side of the first gate electrode; and
a second transistor including
a second gate electrode formed on the semiconductor region with a second gate insulating film interposed therebetween,
a second sidewall formed on a side surface of the second gate electrode,
a third sidewall formed outside the second sidewall, and
second source/drain regions, each formed in an upper portion of the semiconductor region at a side of the second gate electrode, wherein
a silicide layer is formed in each of upper portions of the first gate electrode and the first source/drain regions in the first transistor,
no silicide layer is formed in each of upper portions of the second gate electrode and the second source/drain regions in the second transistor, and
the first sidewall is resistant to an etching material used for etching the third sidewall.

2. The semiconductor device of claim 1, wherein
the first sidewall and the second sidewall are made of silicon oxide, and
the third sidewall is made of silicon nitride.

3. The semiconductor device of claim 1, wherein
the first sidewall and the second sidewall are made of silicon nitride, and
the third sidewall is made of silicon oxide.

4. The semiconductor device of claim 1, wherein
a first protective film and a second protective film are sequentially formed on the second transistor so that the first protective film is closer to the semiconductor region than the second protective film,
the first protective film has an etching rate equal to or higher than that of the third sidewall with respect to the etching material, and
the second protective film is resistant to the etching material.

5. The semiconductor device of claim 4, wherein
the first protective film is made of silicon nitride, and
the second protective film is made of silicon oxide.

6. The semiconductor device of claim 1, wherein
a third protective film is formed on the second transistor, and
the third protective film has an etching rate equal to that of the third sidewall with respect to the etching material.

7. The semiconductor device of claim 6, wherein
the third protective film is made of silicon oxide.

8. The semiconductor device of claim 1, further comprising
a liner film formed to cover the first transistor and the second transistor.

9. A manufacturing method of a semiconductor device comprising the steps of:
(a) sequentially forming a first gate insulating film and a first gate electrode in a silicide formation region on a semiconductor region, and sequentially forming a second gate insulating film and a second gate electrode in a non-silicide-formation region on the semiconductor region;
(b) sequentially forming a first sidewall on a side surface of the first gate insulating film and a side surface of the first gate electrode, and a second sidewall on a side surface of the second gate insulating film and a side surface of the second gate electrode;
(c) after the step (b), forming first source/drain regions, each formed in an upper portion of the semiconductor region at a side of the first gate electrode, and forming second source/drain regions, each formed in an upper portion of the semiconductor region at a side of the second gate electrode;
(d) after the step (c), sequentially forming a first protective film and a second protective film above the semiconductor region from the silicide formation region to the non-silicide-formation region;
(e) selectively removing the second protective film included in the silicide formation region;
(f) removing the first protective film and the second sidewall in the silicide formation region using the second protective film remaining in the non-silicide-formation region as a mask; and
(g) forming a metal silicide layer in each of upper portions of the first gate electrode and the first source/drain regions by forming a metal film on the semiconductor region and heating the formed metal film, while forming no metal silicide layer in each of upper portions of the second gate electrode and the second source/drain regions.

10. The method of claim 9, further comprising the step of
(h) after the step (g), forming a liner film from the silicide formation region to the non-silicide-formation region.

11. The method of claim 9, further comprising the step of
(i) after the step (g), removing the second protective film and the first protective film in the non-silicide-formation region.

12. The method of claim 9, wherein
the first sidewall and the second protective film are made of silicon oxide, and
the second sidewall and the first protective film are made of silicon nitride.

13. A manufacturing method of a semiconductor device comprising the steps of:
(a) sequentially forming a first gate insulating film and a first gate electrode in a silicide formation region on a semiconductor region, and sequentially forming a second gate insulating film and a second gate electrode in a non-silicide-formation region on the semiconductor region;
(b) sequentially forming a first sidewall on a side surface of the first gate insulating film and a side surface of the first gate electrode, and a second sidewall on a side surface of the second gate insulating film and a side surface of the second gate electrode;
(c) after the step (b), forming first source/drain regions, each formed in an upper portion of the semiconductor region at a side of the first gate electrode, and forming second source/drain regions, each formed in an upper portion of the semiconductor region at a side of the second gate electrode;
(d) after the step (c), forming a protective film above the semiconductor region from the silicide formation region to the non-silicide-formation region;
(e) selectively removing the protective film and the second sidewall included in the silicide formation region; and
(f) forming a metal silicide layer in each of upper portions of the first gate electrode and the first source/drain regions by forming a metal film on the semiconductor region and heating the formed metal film.

14. The method of claim 13, further comprising the step of
(g) after the step (f), forming a liner film from the silicide formation region to the non-silicide-formation region.

15. The method of claim 13, further comprising the step of
(h) after the step (f), removing the protective film in the non-silicide-formation region.

16. The method of claim 13, wherein
the first sidewall is made of silicon nitride, and
the second sidewall and the protective film are made of silicon oxide.
